(19) United States
(12) Patent Application Publication
(10) Pub. No.: US 2013/0175153 A1
(43) Pub. Date: Jul. 11, 2013

(54) THIN CAPACITIVE TOUCH PANEL

(71) Applicant: CHIN-FU CHANG, Taipei City (TW)

(72) Inventor: CHIN-FU CHANG, Taipei City (TW)

(73) Assignee: EGALAX_EMPIA TECHNOLOGY INC., Taipei City (TW)

(21) Appl. No.: 13/609,426

(22) Filed: Sep. 11, 2012

(30) Foreign Application Priority Data
Jan. 6, 2012 (TW) 101100531

(51) Int. Cl. H03K 17/975

(52) U.S. Cl. 200/600

(57) ABSTRACT

The present invention proposes a thin capacitive touch panel that includes a plurality of conductive strips, a surface glass and a hydrophobic material. The conductive strips include a grid consisting of a plurality of crisscrossed first conductive strips arranged in parallel and second conductive strips arranged in parallel. The surface glass is overlaid on the conductive strips with a thickness of less than 0.7 mm. In addition, the hydrophobic material is coated on a surface of the surface glass, forming a hydrophobic surface. When moisture is left on the hydrophobic surface after a finger sweep, the moisture is divided into a plurality of water particles by the hydrophobic surface.

### CROSS REFERENCE TO RELATED APPLICATIONS

This application claims the benefit of TW Application No. 101100531, filed on Jan. 6, 2012, which are herein incorporated by reference for all intents and purposes.

### BACKGROUND OF THE INVENTION

1. Field of the Invention

The present invention relates to a touch panel, and more particularly, to a thin capacitive touch panel that includes a hydrophobic surface.

2. Description of the Prior Art

Referring to FIG. 1A, the surface of a touch panel is usually made of glass 11 with numerous tiny concave and convex structures thereon that trap water 12 easily. Sometimes, a finger 13 may excrete sweat, so after the finger sweeps across the touch panel surface, it leaves a water mark 14 on the touch panel, as shown in FIG. 1B.

Referring still to FIG. 1B, a capacitive touch panel 15 includes a plurality of first conductive strips 16 and second conductive strips 17. During detection, differences in signals on the conductive strips before and after touch are compared to detect the location of the touch. The water mark 14 may cross over several conductive strips, and capacitive coupling may exist between the water in the water mark 14 and the conductive strips. Thus, due to capacitive couplings between water in the water mark 14, a signal on a conductive strip may flow to other conductive strips capacitive coupled with the water in the water mark 14.

When the surface layer of the touch panel is thicker, the distance between the conductive strips and the surface of the touch panel is larger, and signals produced due to the above flow action are weak and has small influence on the determination of the location. However, if the water mark is on a thin capacitive touch panel, then signals due to this flow action may cause significant differences in the detected signals, resulting in phantom touches.

From the above it is clear that prior art still has shortcomings. In order to solve these problems, efforts have long been made in vain, while ordinary products and methods offering no appropriate structures and methods. Thus, there is a need in the industry for a novel technique that solves these problems.

### SUMMARY OF THE INVENTION

One objective of the present invention is to solve the problem of phantom touches caused by water marks left on thin capacitive touch panels as a result of sweaty fingers. By applying a layer of hydrophobic material on a thin capacitive touch panel having a surface glass thickness of 0.7 mm or less, moisture left on the surface of the panel after a finger sweep can be divided into several water particles, preventing water from bridging over two or more conductive strips. This eliminates the generation of additional capacitive couplings, and thus prevents the occurrence of phantom touches.

The above and other objectives of the present invention can be achieved by the following technical scheme. The present invention proposes a thin capacitive touch panel, which may include a plurality of conductive strips, a surface glass and a hydrophobic material. The conductive strips include a grid consisting of a plurality of crisscrossed first conductive strips arranged in parallel and second conductive strips arranged in parallel. The surface glass is overlaid on the conductive strips with a thickness of less than 0.7 mm. The hydrophobic material is coated on a surface of the surface glass, forming a hydrophobic surface. When moisture is left on the hydrophobic surface after a finger sweep, the moisture is divided into a plurality of water particles by the hydrophobic surface, and each water particle is smaller than a minimum gap between the parallel-arranged conductive strips, avoiding the formation of water films bridging over multiple conductive strips as a result of moisture agglomeration.

The above and other objectives of the present invention can also be achieved by the following technical measures.

The above hydrophobic surface may include a plurality of protrusions made of the hydrophobic material, wherein the water particles are on top of the protrusions.

The above hydrophobic surface may include a plurality of hydrophobic regions made of the hydrophobic material, and the hydrophobic regions separate a plurality of water-containing spaces, wherein the water particles are in the water-containing spaces.

The above hydrophobic surface may include a plurality of hydrophobic regions made of the hydrophobic material and a plurality of hydrophilic regions, and the hydrophilic regions are separated by the hydrophobic regions, wherein the water particles are in the hydrophilic regions.

The above and other objectives of the present invention can also be achieved by the following technical scheme. The present invention proposes a thin capacitive touch panel, which may include a plurality of conductive strips, a surface glass and a hydrophobic-hydrophilic compound. The conductive strips include a grid consisting of a plurality of crisscrossed first conductive strips arranged in parallel and second conductive strips arranged in parallel. The surface glass is overlaid on the conductive strips with a thickness of less than 0.7 mm. The hydrophobic-hydrophilic compound is coated on a surface of the surface glass, forming a plurality of hydrophobic regions and a plurality of hydrophilic regions separated by the hydrophobic regions. When moisture is left on the hydrophobic-hydrophilic compound after a finger sweep, the moisture is divided into a plurality of water particles by the hydrophobic-hydrophilic compound, and each water particle is smaller than a minimum gap between the parallel-arranged conductive strips, avoiding the formation of water films bridging over multiple conductive strips as a result of moisture agglomeration.

The above description is only an outline of the technical schemes of the present invention. Preferred embodiments of the present invention are provided below in conjunction with the attached drawings to enable one with ordinary skill in the art to better understand said and other objectives, features and advantages of the present invention and to make the present invention accordingly.

### BRIEF DESCRIPTION OF THE DRAWINGS

The present invention can be more fully understood by reading the following detailed description of the preferred embodiments, with reference made to the accompanying drawings, wherein:

FIG. 1A is a schematic diagram depicting a touch panel with water on the surface thereof in the prior art;

FIG. 1B is a schematic diagram depicting a water mark formed on the surface of the touch panel after a finger sweep in the prior art;

FIG. 2A is a schematic diagram illustrating the structure of a hydrophobic material based on a first example of the present invention;

FIG. 2B is a schematic diagram illustrating the structure of a hydrophobic material based on a second example of the present invention; and

FIG. 3 is a schematic diagram illustrating the structure of a hydrophobic material based on a third example of the present invention.

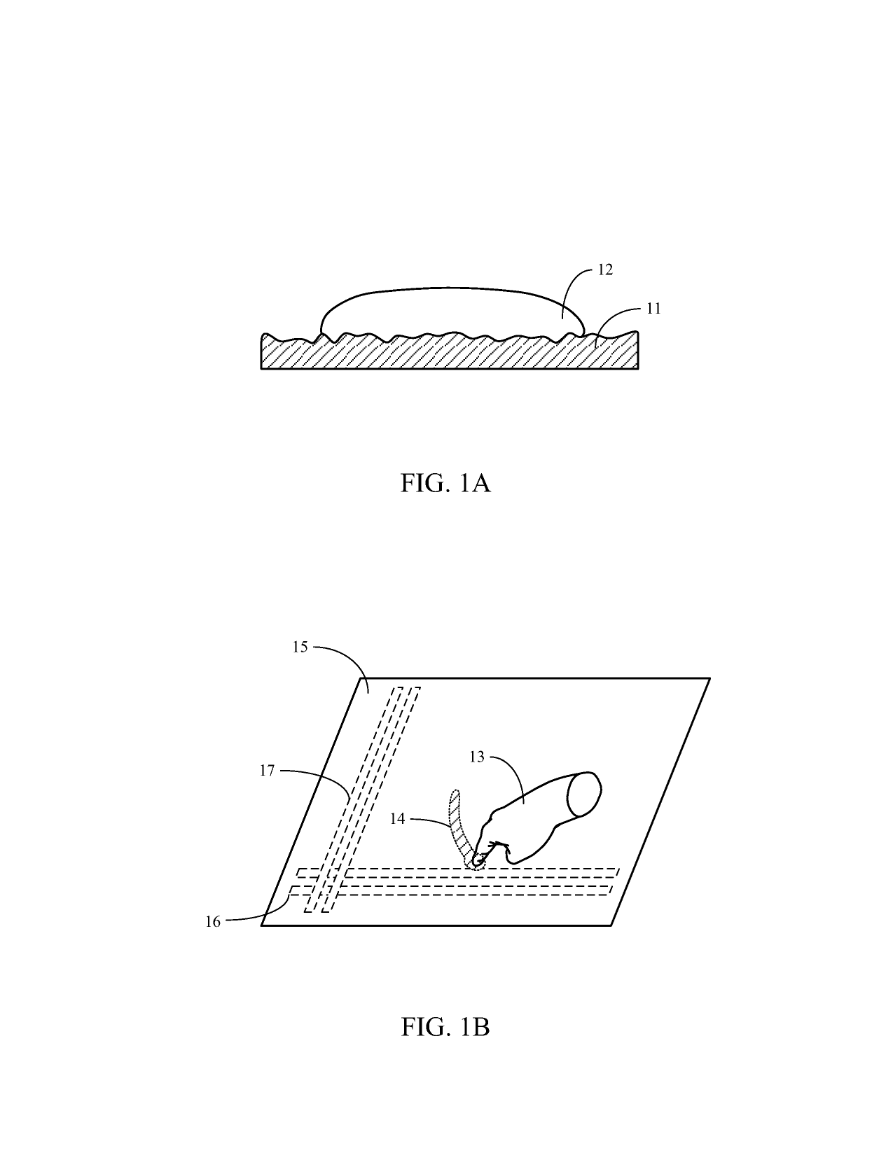

### DETAILED DESCRIPTION OF THE PREFERRED EMBODIMENTS

Some embodiments of the present invention are described in details below. However, in addition to the descriptions given below, the present invention can be applicable to other embodiments, and the scope of the present invention is not limited by such, rather by the scope of the claims. Moreover, for better understanding and clarity of the description, some components in the drawings may not necessary be drawn to scale, in which some may be exaggerated relative to others, and irrelevant parts are omitted.

According to the thin capacitive touch panel proposed by the present invention, a layer of hydrophobic material is coated on the capacitive touch panel, wherein the thickness of the surface glass on the capacitive touch panel is equal or less than 7 mm. The said capacitive touch panel includes a plurality of conductive strips with a plurality of first conductive strips and a plurality of second conductive strips. The first and second conductive strips intersect each other, and are separated with a dielectric material. In an example of the present invention, the first conductive strips are arranged in parallel with one another, and the second conductive strips are also arranged in parallel with one another.

The hydrophobic material forms a “lotus effect” on the panel surface, which divides the moisture left on the panel surface after a finger sweep into numerous small water particles. Each water particle is much smaller than the minimum gap between the parallel conductive strips.

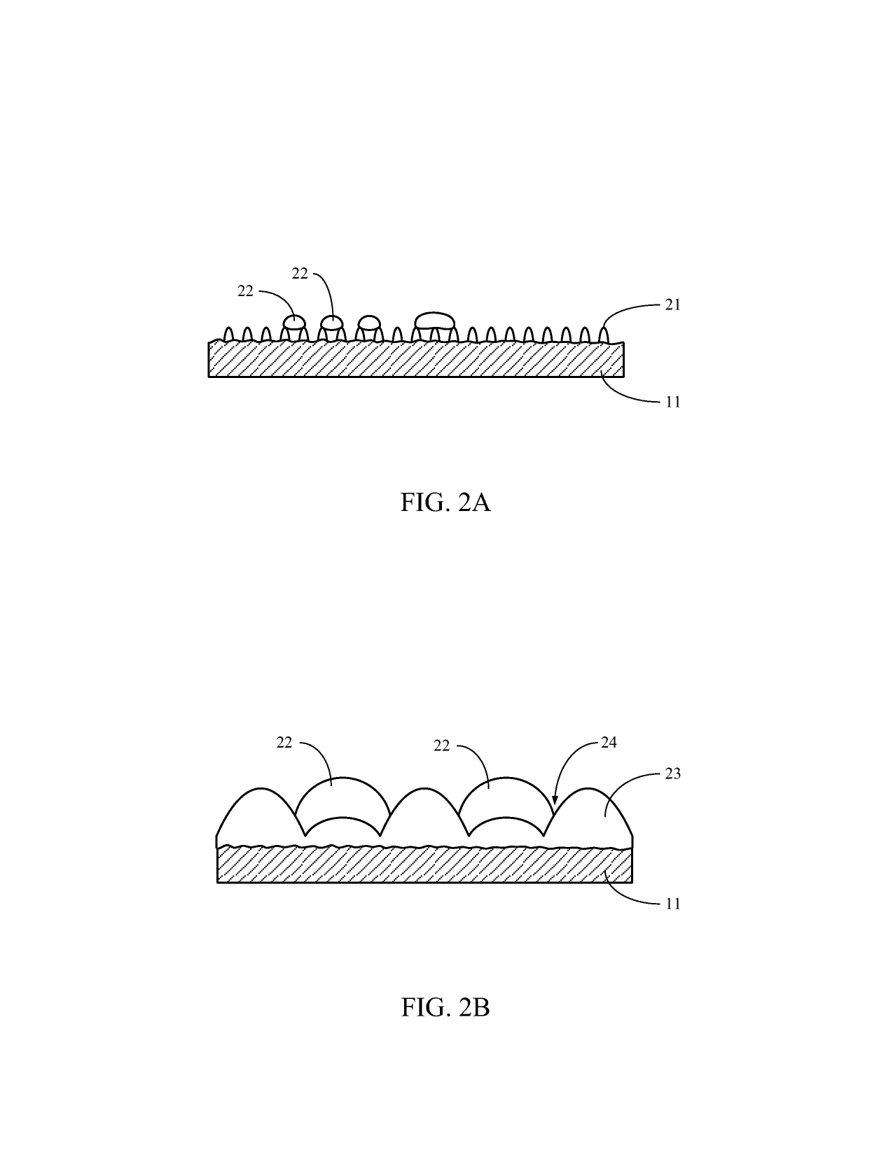

In an example of the present invention, as shown in FIG. 2A, the hydrophobic material forms a plurality of small protrusions 21 on the panel surface. The moisture left on the panel surface after a finger sweep is divided into several small water particles 22 on top of the protrusions 21. In another example of the present invention, as shown in FIG. 2B, the hydrophobic material forms a plurality of hydrophobic regions 23 on the panel surface. These hydrophobic regions 23 partitions the panel surface into a plurality of water-containing spaces 24. The moisture left on the panel surface after a finger sweep is divided into several small water particles 22 in the water-containing spaces 24.

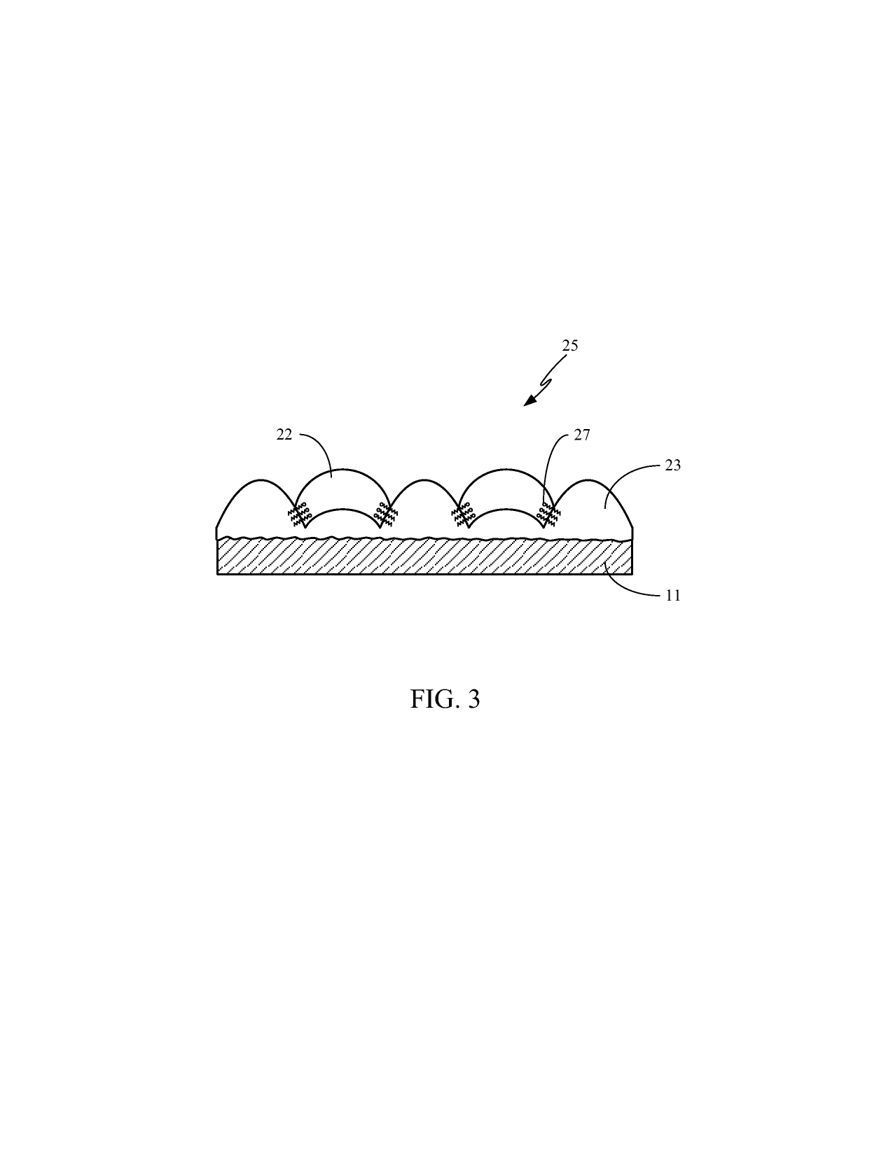

In yet another example of the present invention, as shown in FIG. 3, the hydrophobic material forms a plurality of hydrophobic regions 23 on the panel surface. There are hydrophilic materials 27 between the hydrophobic regions 23, thus forming a plurality of hydrophilic regions 25. The moisture left on the panel surface after a finger sweep can be divided into several small water particles 22 agglomerated in the hydrophilic regions 25 and separated by the hydrophobic regions 23. The hydrophilic regions 25 may be continuously surrounded by a hydrophobic material, or non-continuously surrounded by protrusions formed of hydrophobic material.

In the case of a glass surface without hydrophobic material, the moisture left on the panel surface after a finger sweep will form a large patch or several small patches of water film(s). When a water film bridges over two parallel conductive strips, additional capacitive couplings may be generated via the water film, resulting in phantom touches.

However, with the hydrophobic material coated on the surface of the panel as proposed by the present invention, the moisture left on the panel surface after a finger sweep is divided into independent small water particles, preventing the generation of water films bridging over multiple conductive strips, thus eliminating the additional capacitive coupling generated by the water film crossing over conductive strips. This gives a more accurate touch determination for the touch panel.

The thinner the surface glass, the greater the influence of the additional capacitive coupling caused by water films bridging multiple conductive strips. The influence is even more prominent especially when the thickness of the surface glass is equal to or less than 0.7 mm.

In addition, since the moisture left by the finger is divided into minute water particles, they will evaporate more easily. Especially when the capacitive touch panel is provided in front of a display, heat generated by the radiation of the display will speed up the evaporation of the water particles.

The hydrophobic material can be a curable coating cured on the surface of the panel by temperature (thermal curing), moisture (e.g. typically used in sol-gel reaction), chemical reaction (chemical curing) or optical reaction (e.g. ultraviolet radiation curing). The hydrophobic material can also be temporarily coated on the panel surface, such as by spraying.

Thus, a thin capacitive touch panel according to an embodiment proposed by the present invention includes a plurality of conductive strips, a surface glass and a hydrophobic material. The conductive strips include a grid consisting of a plurality of crisscrossed first conductive strips arranged in parallel and second conductive strips arranged in parallel. The surface glass is overlaid on the conductive strips and is less than 0.7 mm in thickness. In addition, the hydrophobic material is coated on the surface of the surface glass forming a hydrophobic surface. When moisture is left on the hydrophobic surface after a finger sweep, the moisture is divided into a plurality of water particles by the hydrophobic surface. Each water particle is smaller than the minimum gap between the parallel-arranged conductive strips, avoiding the formation of water films bridging over multiple conductive strips as a result of moisture agglomeration.

In an example of the present invention, the hydrophobic surface includes a plurality of protrusions made of the hydrophobic material. The water particles are on the top of the protrusions. In another example of the present invention, the hydrophobic surface includes a plurality of hydrophobic regions made of the hydrophobic material. The hydrophobic regions separate a plurality of water-containing spaces, wherein the water particles are in the water-containing spaces. In an example of the present invention, the hydrophobic surface includes a plurality of hydrophobic regions made of the hydrophobic material and a plurality of hydrophilic regions. The hydrophilic regions are separated by the hydrophobic regions, wherein the water particles are in the hydrophilic regions.

Moreover, a thin capacitive touch panel according to another embodiment proposed by the present invention includes a plurality of conductive strips, a surface glass and a hydrophobic-hydrophilic compound. The conductive strips include a grid consisting of a plurality of crisscrossed first conductive strips arranged in parallel and second conductive strips arranged in parallel. The surface glass is overlaid on the conductive strips and is less than 0.7 mm in thickness. In addition, the hydrophobic-hydrophilic compound is coated on the surface of the surface glass forming a plurality of hydrophobic regions and a plurality of hydrophilic regions separated by the hydrophobic regions. When moisture is left on the hydrophobic surface after a finger sweep, the moisture is divided into a plurality of water particles by the hydrophobic-hydrophilic compound. Each water particle is smaller than the minimum gap between the parallel-arranged conductive strips, avoiding the formation of water films bridging over multiple conductive strips as a result of moisture agglomeration.

The above embodiments are only used to illustrate the principles of the present invention, and they should not be construed as to limit the present invention in any way. The above embodiments can be modified by those with ordinary skill in the art without departing from the scope of the present invention as defined in the following appended claims.

What is claimed is:

1. A thin capacitive touch panel, comprising:
a plurality of conductive strips including a grid consisting of a plurality of crisscrossed first conductive strips arranged in parallel and second conductive strips arranged in parallel;
a surface glass overlaid on the conductive strips with a thickness of less than 0.7 mm; and
a hydrophobic material coated on a surface of the surface glass forming a hydrophobic surface,
wherein when moisture is left on the hydrophobic surface after a finger sweep, the moisture is divided into a plurality of water particles by the hydrophobic surface, and each water particle is smaller than a minimum gap between the parallel-arranged conductive strips, avoiding the formation of water films bridging over multiple conductive strips as a result of moisture agglomeration.

2. The thin capacitive touch panel of claim 1, wherein the hydrophobic surface includes a plurality of protrusions made of the hydrophobic material, wherein the water particles are on top of the protrusions.

3. The thin capacitive touch panel of claim 1, wherein the hydrophobic surface includes a plurality of hydrophobic regions made of the hydrophobic material, and the hydrophobic regions separate a plurality of water-containing spaces, wherein the water particles are in the water-containing spaces.

4. The thin capacitive touch panel of claim 1, wherein the hydrophobic surface includes a plurality of hydrophobic regions made of the hydrophobic material and a plurality of hydrophilic regions, and the hydrophilic regions are separated by the hydrophobic regions, wherein the water particles are in the hydrophilic regions.

5. The thin capacitive touch panel of claim 4, wherein a surface of the hydrophilic regions includes a hydrophilic material.

6. A thin capacitive touch panel, comprising:
a plurality of conductive strips including a grid consisting of a plurality of crisscrossed first conductive strips arranged in parallel and second conductive strips arranged in parallel;
a surface glass overlaid on the conductive strips with a thickness of less than 0.7 mm; and
a hydrophobic-hydrophilic compound coated on a surface of the surface glass forming a plurality of hydrophobic regions and a plurality of hydrophilic regions separated by the hydrophobic regions,
wherein when moisture is left on the hydrophobic-hydrophilic compound after a finger sweep, the moisture is divided into a plurality of water particles by the hydrophobic-hydrophilic compound, and each water particle is smaller than a minimum gap between the parallel-arranged conductive strips, avoiding the formation of water films bridging over multiple conductive strips as a result of moisture agglomeration.
